(19) United States
(12) Patent Application Publication
(10) Pub. No.: US 2025/0298487 A1
(43) Pub. Date: Sep. 25, 2025

(54) SELECTIVE OBJECT-LEVEL UNDO

(71) Applicant: Adobe Inc., San Jose, CA (US)

(72) Inventors: Nikita Soni, Chicago, IL (US); Trung Bui, San Jose, CA (US); Kevin Gary Smith, Lehi, UT (US)

(21) Appl. No.: 18/610,628

(22) Filed: Mar. 20, 2024

(51) Int. Cl. G06F 3/0481; G06F 3/04842; G06F 3/04845; G06F 30/12

(52) U.S. Cl. CPC G06F 3/0481; G06F 3/04842; G06F 3/04845; G06F 30/12

(57) ABSTRACT

The present disclosure relates to systems, non-transitory computer-readable media, and methods for modifying a digital design by performing a selective object-level undo operation. In one or more embodiments, the disclosed systems generate a modified object by performing a series of operations on an object depicted within the digital design. In some embodiments, the disclosed systems receive a selective object-level undo operation on the modified object, wherein the request specifies an operation to undo from among the series of operations performed on the object. In one or more embodiments, the disclosed systems modify the modified object by performing the selective object-level undo operation on the modified object to undo the operation from among the series of operations. In some embodiments, the disclosed systems provide an updated digital design depicting the modified object reflecting modifications from the series of operations excluding the operation undone by the selective object-level undo operation.

### BACKGROUND

Recent years have seen significant improvement in hardware and software platforms for generating and editing computer graphics. Over time, developers have created technologies to improve digital design platforms for generating and editing designs. For example, conventional graphic design systems often provide editing tools for modifying a digital design at different levels, across an entire design, for certain layers, and/or for specific objects. As part of the editing tools, some conventional systems provide tools for undoing and/or redoing edits. Despite these advances, however, many conventional systems exhibit a number of deficiencies or drawbacks, particularly in flexibility, accuracy, and efficiency.

### SUMMARY

Embodiments of the present disclosure provide benefits and/or solve one or more of the foregoing or other problems in the art with systems, non-transitory computer-readable media, and methods for facilitating selective object-level undo operations within a digital design. For example, the disclosed systems generate a history stream of edits and other operations executed within a digital design. In some embodiments, the disclosed systems track and label various types of operations in the history stream on an object level. In certain cases, the disclosed systems receive a selective object-level undo request and undo a selected operation performed on a specified object. In some embodiments, the disclosed systems further provide interface elements for receiving hybrid undo requests that include audio components (e.g., voice input) and gesture components for selecting objects and/or specifying operations to undo.

### BRIEF DESCRIPTION OF THE DRAWINGS

The detailed description provides one or more embodiments with additional specificity and detail through the use of the accompanying drawings, as briefly described below.

FIG. 1 illustrates an example system environment in which an object-level undo system operates in accordance with one or more embodiments.

FIG. 2 illustrates an overview of generating a modified object utilizing a selective object-level undo operation in accordance with one or more embodiments.

FIG. 3A illustrates an example diagram for utilizing an operation history to generate a modified digital design in accordance with one or more embodiments.

FIG. 3B illustrates an example interface for selectively undoing an operation for an object in a particular layer in accordance with one or more embodiments.

FIG. 4 illustrates an example diagram for modifying an operation history to account for cumulative edit operations in accordance with one or more embodiments.

FIG. 5 illustrates an example diagram for modifying an operation history to account for invalidating operations in accordance with one or more embodiments.

FIG. 6 illustrates an example digital design interface for performing a selective object-level undo operation in accordance with one or more embodiments.

FIG. 7 illustrates an example digital design interface for performing a selective object-level undo operation in accordance with one or more embodiments.

FIG. 8 illustrates a schematic diagram of an object-level undo system in accordance with one or more embodiments.

FIG. 9 illustrates a flowchart of a series of acts for modifying a digital design by performing a selective object-level undo operation in accordance with one or more embodiments.

FIG. 10 illustrates a block diagram of an example computing device for implementing one or more embodiments of the present disclosure.

### DETAILED DESCRIPTION

This disclosure describes one or more embodiments of an object-level undo system that performs or executes selective object-level undo operations with digital designs. For example, based on client device interaction from a designer, the object-level undo system generates a digital design that includes or depicts one or more digital objects. Throughout the creation process, the object-level undo system modifies depicted objects based on interactions with the client device indicating various edits or other operations over the course of the design. In some embodiments, the object-level undo system receives a request to perform a selective object-level undo operation specifying an operation to undo from among a series of operations performed on a particular object. In response to the request, in certain cases, the object-level undo system performs the selective object-level undo operation to undo the selected operation for the selected object, leaving other operations and objects intact.

As just mentioned, in some embodiments, the object-level undo system performs selective object-level undo operations. For instance, the object-level undo system determines and undoes a specified operation for a specified object while retaining or maintaining other operations performed on the object (and on other objects) of the digital design. To undo the operation, in some cases, the object-level undo system modifies the object to reflect a series of edits or operations performed on the object over the course of the design process, excluding or removing (only) the indicated operation. In some embodiments, the object-level undo system receives client device interactions including audio (e.g., voice) components and/or gesture components specifying the object and/or the operation to undo.

To facilitate selective object-level undo operations, in one or more embodiments, the object-level undo system generates and maintains a history stream. For example, the object-level undo system maintains a global operation history for a digital design, labeling each operation with its operation type, a timestamp, and/or the object(s) to which the operation is applied. In some embodiments, the object-level undo system further modifies the operation history to account for cumulative operations that build on one another in an ordered sequence and/or invalidating operations that invalidate (or render moot) one or more previous operations. In some cases, to perform a selective object-level undo operation, the object-level undo system removes or rewinds all operations performed on the object within the object history, removes or undoes the indicated operation, and automatically reapplies subsequent operations.

As indicated above, in some embodiments, the object-level undo system provides various user interface elements to facilitate selective object-level undo requests. For example, the object-level undo system generates and provides interface elements for hybrid request inputs that jointly include both audio (e.g., voice) components and gesture components, whether either or both components indicate objects and/or operations to undo. As another example, the object-level undo system generates and provides an (circular) undo element that is draggable or scrollable in a circular motion to rewind operations and/or to select a particular operation to undo.

As suggested above, many conventional graphical design systems exhibit a number of shortcomings or disadvantages, particularly in how inflexibly conventional systems apply undo operations. Graphics design is a non-linear process that involves many edit operations in no particular order. Despite the non-linear nature of graphics design, many existing systems rigidly force artificial linear operation timelines for undoing edit operations, often limited to undoing operations in reverse chronological order on a design-wide basis. Indeed, to undo an intermediate operation (e.g., an operation that occurred during the design process, not as a final operation) on a particular object in a design, existing systems generally require walking back or undoing each successive operation across the entire design that occurred after the desired operation until finally undoing the desired operation, irrespective of which object(s) the successive edits were applied. Moreover, because undoing an operation within a linear timeline breaks the operation chain that drives undo functionality in many existing systems, these systems rigidly require manual client device interaction to reapply undone operations.

Do at least in part to their inflexibilities, many existing systems are inaccurate. For example, because existing systems often break linear operation chains when undoing an intermediate operation, these systems lose information for edit operations performed after an undone operation. Accordingly, the modified version of an object or a digital design inaccurately reflects the edit operations previously processed and applied. Additionally, existing systems require manual client device interactions to reapply undone edit operations which frequently results in inaccurate variations of originally created designs, as designers often forget (or are otherwise unable) to apply the same edits in the same way after an undo operation.

Due at least in part to their inaccuracies, many existing systems are computationally inefficient. For example, because existing systems often lose edit operations down the operation chain from an undone operation, these systems require processing many redundant edit operations and client device interactions during the process of reapplying subsequent edits. Consequently, many existing systems consume excessive amounts of computing resources, such as processing power and memory, in processing redundant operations and client device interactions.

As suggested above, embodiments of the object-level undo system provide certain improvements or advantages over conventional graphical design systems. For example, embodiments of the object-level undo system improve the flexibility of undoing edits in a digital design by performing selective object-level undo operations. Specifically, the object-level undo system enables undoing a specified (type of) operation performed on a particular object while retaining other operations, even if the other operations are performed after the undone operation and/or even if other objects are edited after the undone operation. To facilitate selective object-level undo operations, the object-level undo system generates and maintains a history stream of edit operations, including object labels and operation labels for edit operations performed across a digital design. In some embodiments, the object-level undo system further accounts for cumulative operations and invalidating operations by excluding certain operations from an event history and/or by merging or consolidating operations together within the history stream, as described further below.

Due at least in part to improving flexibility over existing systems, one or more embodiments of the object-level undo system also improve accuracy over existing systems. Whereas prior systems often generate inaccurate digital designs due to lost information in broken operation chains (e.g., where operations subsequent to an undone operation are lost or deleted from memory), the object-level undo system generates more accurate digital designs by retaining (or automatically reapplying) edit operations performed subsequent to an undone operation. Indeed, the object-level undo system utilizes an operation history stream to track a series of operations for an object modified in a digital design, facilitating a selective object-level undo operation while accounting for cumulative and invalidating edits.

In addition, certain embodiments of the object-level undo system provide improved computational efficiency over existing graphical design systems. For instance, compared to prior systems that re-process many redundant edit operations applied by repetitive client device interactions (due to broken operation chains that lose subsequent edits after tracking back to undo a particular operation), the object-level undo system processes fewer redundantly applied operations. Indeed, by preserving or retaining non-undone edits (even those after an undone edit), the object-level undo system reduces the processing and memory requirements expended by prior systems that handle excessive client device interactions and that process corresponding edit operations manually reapplied by the interactions.

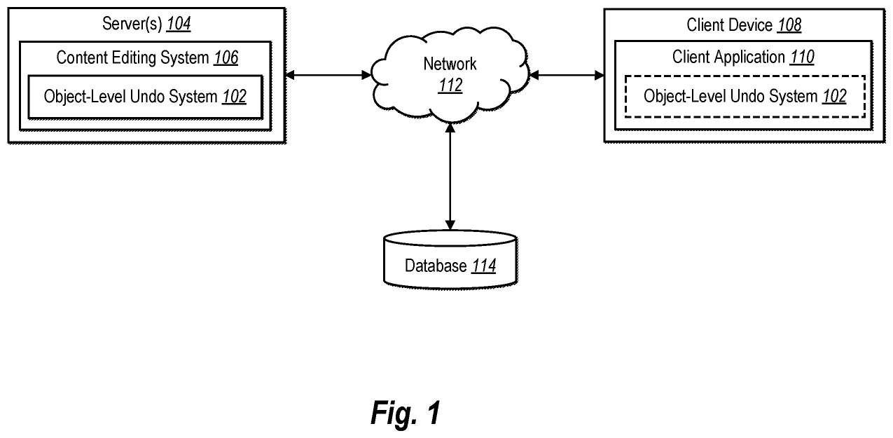

Additional detail regarding the object-level undo system will now be provided with reference to the figures. For example, FIG. 1 illustrates a schematic diagram of an example system environment for implementing an object-level undo system 102 in accordance with one or more embodiments. An overview of the object-level undo system 102 is described in relation to FIG. 1. Thereafter, a more detailed description of the components and processes of the object-level undo system 102 is provided in relation to the subsequent figures.

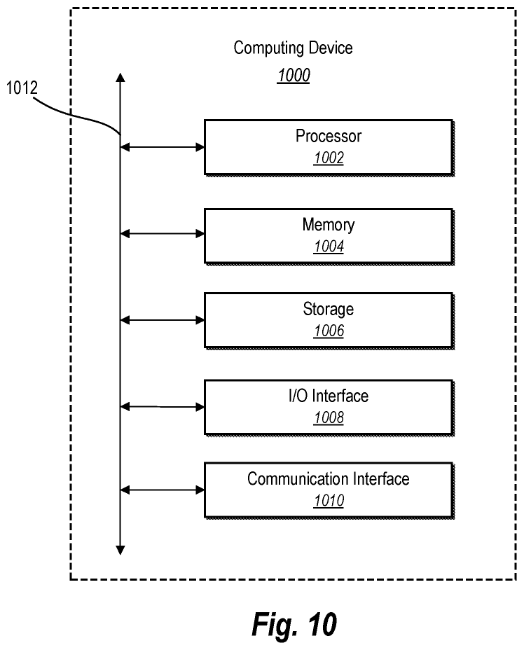

As shown, the environment includes server(s) 104, a client device 108, a database 114, and a network 112. Each of the components of the environment communicate via the network 112, and the network 112 is any suitable network over which computing devices communicate. Example networks are discussed in more detail below in relation to FIG. 10.

As mentioned, the environment includes a client device 108. The client device 108 is one of a variety of computing devices, including a smartphone, a tablet, a smart television, a desktop computer, a laptop computer, a virtual reality device, an augmented reality device, or another computing device as described in relation to FIG. 10. Although FIG. 1 illustrates a single instance of the client device 108, in some embodiments, the environment includes multiple different client devices, each associated with a different user (e.g., digital design editor). The client device 108 communicates with the server(s) 104 and/or the digital content editing system 106 via network 112. For example, the client device 108 receives user interactions to generate and edit objects in a digital design and provides information to server(s) 104 indicating the edits and corresponding metadata (e.g., object labels, timestamps, and operation types).

As shown in FIG. 1, the client device 108 includes a client application 110. In particular, the client application 110 is a web application, a native application installed on the client device 108 (e.g., a mobile application or a desktop application), or a cloud-based application where all or part of the functionality is performed by the server(s) 104. The client application 110 presents or displays information to a user, including digital design interfaces for generating, editing, modifying, or visualizing digital designs that include various objects and interface elements for selecting object-level operations to undo. In some embodiments, the client application 110 executes, houses, or operates all or a portion of the object-level undo system 102.

As also illustrated in FIG. 1, the environment includes the server(s) 104. The server(s) 104 generates, tracks, stores, processes, receives, and transmits electronic data, such as edits, selective object-level undo operations, and selections of interface elements. For example, the server(s) 104 receives data from the client device 108 in the form of interaction data requesting a selective object-level undo operation via an interface element. In response, the server(s) 104 provides data to the client device 108 in the form of a modified digital design depicting an object modified by undoing a selected edit displayable at the client device 108.

In some embodiments, the server(s) 104 communicates with the client device 108 to transmit and/or receive data via the network 112. In some embodiments, the server(s) 104 comprises a distributed server where the server(s) 104 includes a number of server devices distributed across the network 112 and located in different physical locations. The server(s) 104 comprise a content server, an application server, a communication server, a web-hosting server, a multidimensional server, or a machine learning server.

As further shown in FIG. 1, the server(s) 104 also includes the object-level undo system 102 as part of a digital content editing system 106. For example, in one or more implementations, the digital content editing system 106 stores, generates, modifies, edits, enhances, provides, distributes, and/or shares digital content, such as digital images, digital text, or digital videos. For example, the digital content editing system 106 provides digital content for editing or other forms of digital processing. In some implementations, the digital content editing system 106 provides digital content to particular digital profiles associated with client devices (e.g., the client device 108).

In one or more embodiments, the server(s) 104 includes all, or a portion of, the object-level undo system 102. For example, the object-level undo system 102 operates on the server(s) 104 to generate and modify objects via selective object-level undo operations. In some embodiments, the client device 108 includes all or part of the object-level undo system 102. For example, the client device 108 generates, obtains (e.g., downloads), or uses one or more aspects of the object-level undo system 102 from the server(s) 104, such as one or more machine learning models for performing selective object-level undo operations. Indeed, in some implementations, as illustrated in FIG. 1, the object-level undo system 102 is located in whole or in part of the client device 108 (e.g., as part of the client application 110). For example, the object-level undo system 102 includes a web hosting application that allows the client device 108 to interact with the server(s) 104. To illustrate, in one or more implementations, the client device 108 accesses a web page supported and/or hosted by the server(s) 104.

As shown in FIG. 1, the environment includes a database 114. For example, the server(s) 104 communicate with the database 114 to access stored digital designs, objects to import into digital designs, and/or machine learning models trained to identify depicted objects in designs. In some cases, the database 114 is housed, managed, or maintained by the server(s) 104. In other cases, the database 114 is a third-party database accessible via the network 112 but not managed by the server(s) 104.

In one or more embodiments, the client device 108 and the server(s) 104 work together to implement the object-level undo system 102. For example, in some embodiments, the server(s) 104 train one or more machine learning models (e.g., neural networks for identifying depicted objects) and provide the one or more machine learning models to the client device 108 for implementation. In some embodiments, the server(s) 104 trains one or more neural networks together with the client device 108.

Although FIG. 1 illustrates a particular arrangement of the environment, in some embodiments, the environment has a different arrangement of components and/or may have a different number or set of components altogether. For instance, as mentioned, the object-level undo system 102 is implemented by (e.g., located entirely or in part on) the client device 108. In addition, in one or more embodiments, the client device 108 communicates directly with the object-level undo system 102, bypassing the network 112.

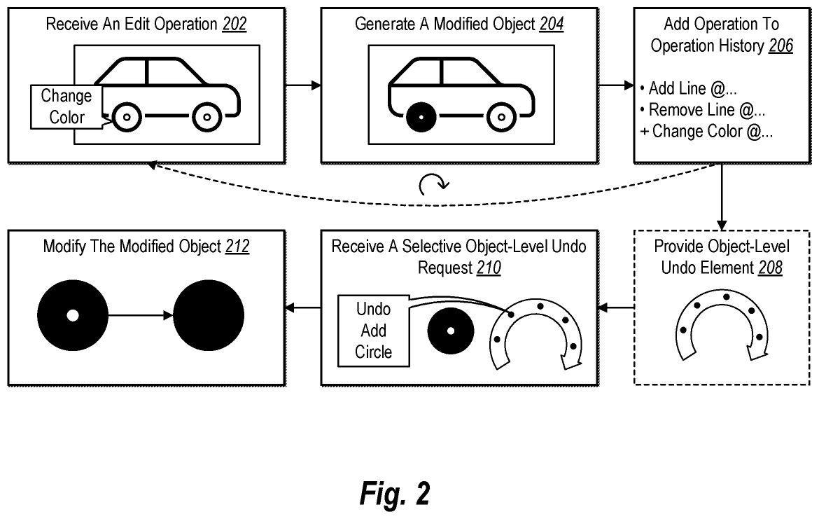

As mentioned, in one or more embodiments, the object-level undo system 102 performs selective object-level undo operations. In particular, the object-level undo system 102 receives a request to undo a specified edit operation within an edit timeline of a particular object depicted in a digital design. FIG. 2 illustrates an example overview of performing a selective object-level undo operation in accordance with one or more embodiments. Additional detail regarding the various acts and processes introduced in relation to FIG. 2 is provided thereafter with reference to subsequent figures.

As illustrated in FIG. 2, the object-level undo system 102 performs an act 202 to receive an edit operation. In particular, the object-level undo system 102 receives an edit operation via a client device to change one or more visible or non-visible attributes of a digital design. In some embodiments, a digital design includes or refers to a digital graphic or image that includes or depicts one or more objects. For example, a digital design includes a graphic generated using editing tools of one or more computer applications or platforms for graphic image design and creation. Relatedly, an object includes or refers to a visual subcomponent of a digital design. For instance, an object includes a set of pixels corresponding to a common object label or classification and/or that visually portray a particular entity within a digital design.

As example editing operations, the object-level undo system 102 receives an indication of an interaction creating or modifying an object such as, for example, modifying or adding a color, a size, a shape, a curvature, a weight, a thickness, a line, a curve, a pixel, an opacity, a layer placement, a location, or some other attribute associated with an object depicted in a digital design. Indeed, the object-level undo system 102 provides a computer application environment for generating, manipulating, and editing digital designs that depict one or more objects. An object thus includes a person, place, or thing portrayed within a digital image (as captured by a camera device or generated by a generative model), a vector object within a vector drawing, or a raster object (e.g., collection of pixels portraying a person, place, or thing) within a raster drawing. Within the environment, the object-level undo system 102 provides editing tools for creating and changing various visual and non-visual characteristics of objects within a digital design. As shown, the object-level undo system 102 receives an edit operation to change a color of a particular object within a digital design depicting a car. Namely, the object-level undo system 102 modifies a color of a wheel of the car.

As also illustrated in FIG. 2, the object-level undo system 102 performs an act 204 to generate a modified object. In particular, the object-level undo system 102 generates a modified object by processing an edit operation and applying corresponding changes to a digital design. As shown, the object-level undo system 102 generates a modified wheel by changing its color in response to the edit operation.

Based on executing the edit operation, as further illustrated in FIG. 2, the object-level undo system 102 performs an act 206 to add the operation to an operation history. To elaborate, the object-level undo system 102 updates a history stream of edit operations performed within the digital design. In one or more embodiments, a history stream (or an operation history) includes or refers to a chronological log of edit operations applied to a digital design over time. For example, a history stream includes a time-based listing of operations executed in a digital design, including metadata defining operation parameters for each operation, such as an operation type, pixel locations of pixels modified by the operation, an object label (and/or an instance label) of an object modified by the operation, and/or a timestamp when the operation occurred. As shown, the object-level undo system 102 repeats the act 202, the act 204, and the act 206 to modify a digital design and an operation history for a series of successive edit operations.

In some embodiments, the object-level undo system 102 generates and maintains a global history stream for all edit operations processed on a design-wide basis, across all objects within the overall digital design. In certain cases, the object-level undo system 102 generates and maintains multiple object-level history streams where each object depicted in a digital design has its own respective operation history that includes edit operations (and corresponding metadata defining pixel locations, timestamps, and operation types). As shown, the object-level undo system 102 adds the operation of “change color @ . . . ” to an operation history that already includes other operations, including “add line @ . . . ” and “remove line @ . . . ” listed in chronological order from top to bottom.

As further illustrated in FIG. 2, in one or more embodiments, the object-level undo system 102 performs an act 208 to provide an object-level undo element. More particularly, the object-level undo system 102 generates and provides a user interface element for performing a selective object-level undo operation. For example, based on detecting a selection of an object (e.g., the modified wheel) within a digital design (e.g., the design depicting the car), the object-level undo system 102 provides an object-level undo element for undoing edit operation performed on the selected object. As another example, based on detecting an interaction with a voice input element (e.g., a record element) to record a voice input indicating a depicted object, the object-level undo system 102 provides an object-level undo element for undoing edits performed on the voice-indicated object.

As shown, the object-level undo system 102 generates and provides a circular object-level undo element. In some cases, the object-level undo system 102 the circular element is scrollable or draggable in a circular motion along the element to scroll or navigate through a chronology of edit operations performed on the selected object(s). For example, the object-level undo system 102 generates the circular element to include operation indicators (e.g., the black dots or circles inside the arrow graphic) which each correspond to a respective edit operation applied to the selected object(s). Based on detecting a circular scroll operation (e.g., in a direction from the arrowhead back toward the beginning of the arrow), the object-level undo system 102 navigates in reverse chronological order through a series of edit operations within an operation history.

The object-level undo system 102 can utilize a variety of different object-level undo elements that have different features and shapes. For example, the object-level undo system 102 can utilize a scroll wheel element, a drop-down menu element, a timeline element. Moreover, the the object-level undo system 102 can utilize an element that has a linear, curvilinear, ovular, or square shape. Moreover, the object-level undo system 102 can provide text or audio elements for object-level undo elements.

As further illustrated in FIG. 2, the object-level undo system 102 performs an act 210 to receive a selective object-level undo request. More specifically, the object-level undo system 102 receives an interaction to select a particular operation from among the series of operations along the timeline (e.g., via a circular scroll operation along the arrow). In some cases, the object-level undo system 102 receives the interaction to roll back or rewind the state (and corresponding appearance) of the object to the state when the selected operation was applied. As shown, the object-level undo system 102 receives an interaction to select the second black dot corresponding to an “add circle” operation to undo along the operation timeline.

As illustrated in FIG. 2, the object-level undo system 102 performs an act 212 to modify the modified object. Particularly, the object-level undo system 102 performs or applies the selective object-level undo operation to undo, remove, walk back, or reverse the selected operation. In some cases, the object-level undo system 102 undoes the selected operation by reversing an effect of the selected operation. In some embodiments, the object-level undo system 102 undoes the selected operation by determining and performing an inverse operation of the selected operation. In one or more embodiments, the object-level undo system 102 reverts or rewinds the object back to a state before the selected applied was applied. The object-level undo system 102 thus undoes the selected the operation (and subsequent operation) and reapplies the subsequent operations that occurred after the selected operation (without reapplying the selected operation).

As shown, the object-level undo system 102 undoes the “add circle” operation. Indeed, the object-level undo system 102 undoes the “add circle” operation selected from the series of operations performed in the digital design of the car (and/or from a series of operations performed on the wheel object). By undoing the “add circle” operation, the object-level undo system 102 modifies the wheel object to remove the inner while circle while retaining or preserving other operations, even those performed on the wheel object after the “add circle” operation (including the “change color” operation of the act 202). The object-level undo system 102 further preserves or leaves unchanged operations performed on other objects or components within the digital design, undoing only the selected operation from the series of operations in the history stream.

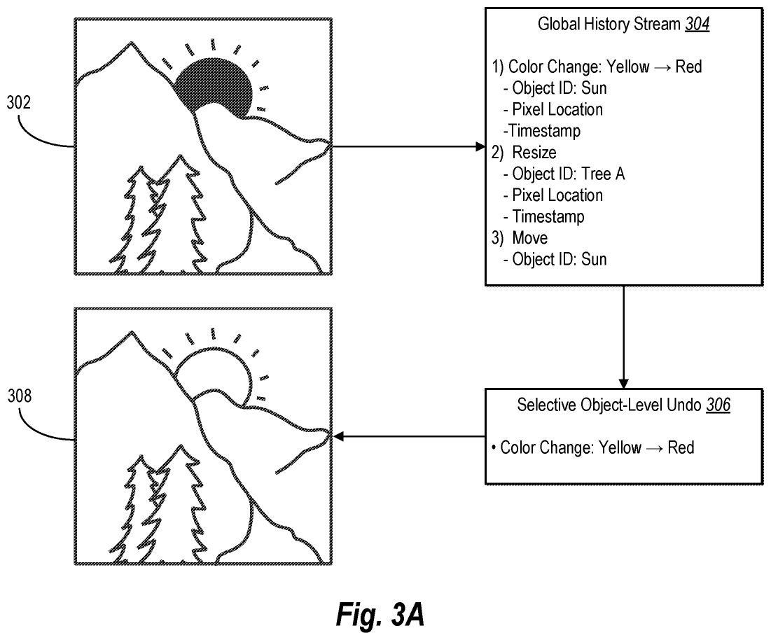

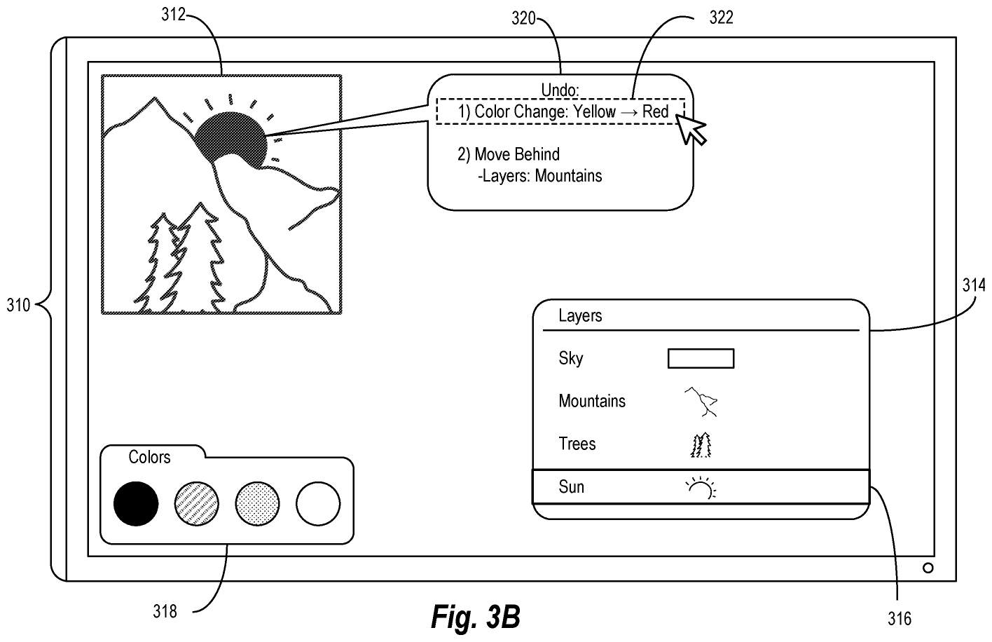

As noted above, in certain described embodiments, the object-level undo system 102 generates and maintains an operation history for a digital design. In particular, the object-level undo system 102 updates an operation history to reflect new edit operations on various objects and/or to remove edit operations undone via a selective object-level undo operation. FIG. 3A illustrates an example diagram for generating and modifying a digital design by updating an operation history based on a selective object-level undo operation in accordance with one or more embodiments.

As illustrated in FIG. 3A, the object-level undo system 102 generates a digital design 302. More particularly, the object-level undo system 102 generates the digital design 302 based on client device interactions within a design environment of a computer application. The object-level undo system 102 further provides the digital design 302 for display on a client device for modification and editing.

In response to receiving edit operations to modify the digital design 302, the object-level undo system 102 generates and modifies an operation history 304 (“Global History Stream”). Indeed, the object-level undo system 102 detects edit operations on various objects in the digital design 302 and, in response, updates the operation history 304 to reflect an updated series of edit operations (e.g., in chronological order). As part of adding edit operations to the operation history 304, the object-level undo system 102 determines operation metadata to include or log for each edit. For example, the object-level undo system 102 determines an operation type of the edit operation, one or more pixel locations affected by the edit operation, an object identifier or label for an object modified by the edit operation, and/or a timestamp of the edit operation. The object-level undo system 102 thus logs the operation metadata within the operation history 304 to monitor and track each edit operation, cataloging operations on an object-specific basis (and/or an operation-type-specific basis).

In some cases, the object-level undo system 102 maintains a global operation history of edit operations performed across the entirety of the digital design 302. In some embodiments, the object-level undo system 102 maintains multiple operation histories, one for each object depicted in the digital design 302. In cases where the object-level undo system 102 maintains object-level operation histories, the object-level undo system 102 generates a new operation history for each object added to the digital design 302 and adds edit operations to respective histories upon detecting modifications of corresponding objects. As shown, the object-level undo system 102 generates the operation history 304 to include three operations: 1) a color change operation to change the sun object from yellow to red, 2) a resize operation to change the Tree A object to a new size, and 3) a move operation to relocate the sun object.

In some embodiments, to identify or detect objects and/or to generate object identifiers/labels, the object-level undo system 102 utilizes one or more object detection models. For example, the object-level undo system 102 utilizes an object detection neural network trained to detect or identify groups of pixels corresponding to particular object labels. In some cases, the object-level undo system 102 utilizes a segmentation neural network to determine boundaries between objects of different labels and/or between different instances of the same object label. For instances, the object-level undo system 102 utilizes an object detection model and/or a (panoptic) segmentation model described by Yuqian Zhou et al. in U.S. patent application Ser. No. 17/520,249, titled DIGITAL IMAGE INPAINTING UTILIZING PLANE PANOPTIC SEGMENTATION AND PLANE GROUPING, filed Nov. 5, 2021 and/or by Zhe Lin et al. in U.S. patent application Ser. No. 17/650,967, titled LEARNING PARAMETERS FOR GENERATIVE INPAINTING NEURAL NETWORKS UTILIZING OBJECT-AWARE TRAINING AND MASKED REGULARIZATION, filed Feb. 14, 2022, both of which are incorporated herein by reference in their entireties.

As further illustrated in FIG. 3A, the object-level undo system 102 performs a selective object-level undo operation 306. To elaborate, the object-level undo system 102 receives a request or a selection of an object-specific edit operation to undo from among the series of operations in the operation history 304. As shown, the object-level undo system 102 receives a request to undo the color change operation.

Based on receiving the request to undo the color change operation, the object-level undo system 102 generates a modified digital design 308. In particular, the object-level undo system 102 generates the modified digital design 308 by modifying the object corresponding to the selected color change operation. Indeed, the object-level undo system 102 reverts or undoes the selected color change operation by modifying the corresponding sun object to reflect a color depicted before the color change operation occurred. As shown, the object-level undo system 102 modifies pixels of the sun object to revert the color back from red to yellow (reversing or undoing the change from yellow to red).

In performing the selective object-level undo operation, the object-level undo system 102 preserves or maintains (all) other operations applied to the digital design 302. For example, the object-level undo system 102 preserves operations performed on other depicted objects as well as other operations performed on the same sun object corresponding to the selected operation. As shown, the object-level undo system 102 undoes the color change operation on the sun while preserving the resize operation and the move operation included in the operation history 304. The object-level undo system 102 thus generates the modified digital design 308 that depicts the sun in its relocated position (from the move operation which occurred on the same sun object after the color change operation) but reverted to yellow after undoing the color change operation.

In one or more embodiments, the object-level undo system 102 performs a selective object-level undo operation on a per-layer basis. In particular, the object-level undo system 102 determines and stores operation histories on a layer-by-layer basis to facilitate selective object-level undo operations. FIG. 3B illustrates performing a layer-specific selective object-level undo operation in accordance with one or more embodiments.

As illustrated in FIG. 3B, the object-level undo system 102 generates and provides an editing interface 310 (e.g., for display on a client device). Within the editing interface 310, the object-level undo system 102 provides a digital design 312 depicting a scene with mountains, trees, a sun, and a lake. The object-level undo system 102 also provides various editing tools for selecting and modifying the digital design 312. For instance, the object-level undo system 102 provides a layers tool 314 for selecting an interacting with various layers of the digital design 312.

As shown in the layers tool 314, the object-level undo system 102 generates different layers for the objects depicted in the digital design 312. For example, the object-level undo system 102 generates a layer for each depicted object and/or generates layers to include multiple objects. In some cases, the object-level undo system 102 receives user interactions to create and label the various layers of the digital design 312. As shown, the object-level undo system 102 generates a sky layer, a mountains layer, a trees layer, and a sun layer, where each layer includes curves or lines defining corresponding objects.

In one or more embodiments, the object-level undo system 102 tracks and stores edit operations on a per-layer basis. For example, the object-level undo system 102 generates an independent operation stack or a history stream for each layer of the digital design 312. In some cases, the operation stack is global, and the object-level undo system 102 labels edit operations with layer labels to designate layers where edits are made. Either way, the object-level undo system 102 generates a timeline edit operations performed on layers of the digital design 312. In some embodiments, the object-level undo system 102 further determines edit operations performed on a per-object basis within a given layer. For instance, the object-level undo system 102 attaches an object label to each edit operation performed within a layer to further designate, within the given layer, an object where an edit operation is applied. Thus, within a layer-specific operation history, the object-level undo system 102 also labels edit operations with object identifiers to track object-specific edits within each layer.

The object-level undo system 102 further performs a selective object-level undo operation for an active layer or a selected layer (and/or for a selected object within a selected layer). Particularly, the object-level undo system 102 receives an indication of a selection of a layer within the digital design 312 and accesses a corresponding set of operations performed on the selected layer (e.g., by identifying a layer-specific operation history). As shown, the object-level undo system 102 receives a selection of the sun layer 316 within the layers tool 314. In response, the object-level undo system 102 determines or accesses a timeline of edit operations performed on the sun layer 316 (e.g., on all objects within the layer). For instance, the object-level undo system 102 determines a first operation to move the sun layer behind the mountains layer within the digital design 312. In addition, the object-level undo system 102 determines a subsequent operation to change a color of the sun object (e.g., via a colors tools 318) from yellow to red.

Based on a selection of the sun layer 316 and/or based on a selection of the sun object within the digital design 312, the object-level undo system 102 provides an undo element 320 for display. Within the undo element 320, the object-level undo system 102 provides a layer-specific (and/or object-specific) operation history for the sun layer 316. As shown, the operation history includes a first operation 322 to change the color of the sun layer from yellow to red and a second operation to move the sun layer behind the mountains layer. As also shown, the object-level undo system 102 receives a user interaction selecting the first operation 322 within the undo element 320. In response to the selection, the object-level undo system 102 performs a selective object-level undo operation to undo the first operation 322 without affecting the second operation and/or without affecting operations performed on other layers or objects within the digital design 312.

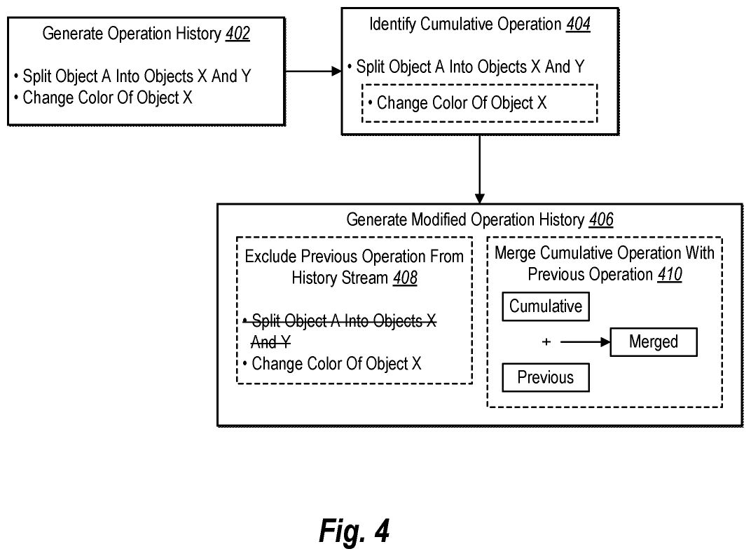

As mentioned above, in one or more embodiments, the object-level undo system 102 generates and updates an operation history to account for cumulative edit operations. In particular, the object-level undo system 102 identifies or detects cumulative edit operations and modifies an operation history accordingly. FIG. 4 illustrates an example diagram for modifying an operation history to account for cumulative edit operations in accordance with one or more embodiments.

As illustrated in FIG. 4, the object-level undo system 102 performs an act 402 to generate an operation history. To generate an operation history, the object-level undo system 102 detects edit operations performed within a digital design and generates operation logs for the edit operations. Indeed, the object-level undo system 102 adds a new operation log to the operation history that includes operation metadata indicating, for example, an object label, an operation type, and a timestamp. Over time, the object-level undo system 102 thus generates an operation history (or multiple object-specific operation histories) that includes a series of edit operations performed in a digital design.

As also illustrated in FIG. 4, the object-level undo system 102 performs an act 404 to identify a cumulative edit operation. In some embodiments, a cumulative operation includes or refers to an edit operation that builds on or relies on one or more previous edit operations. For example, a cumulative operation relies on object parameters generated or modified as a result of previously applying another edit operation during the graphical design process. The object-level undo system 102 identifies or detects a cumulative edit operation by determining that an edit operation builds on a previous operation among the series of operations in the operation history. For example, the object-level undo system 102 determines that an operation is cumulative if it would not be performable without an object modification resulting from a previous operation. As shown, the object-level undo system 102 determines that the operation “change color of object X” is cumulative on the previous operation of “split object A into objects X and Y” because object X would not exist but for the operation to split object A, and the operation to change its color is predicated on the existence of object X.

As further illustrated in FIG. 4, the object-level undo system 102 performs an act 406 to generate a modified operation history. In particular, the object-level undo system 102 modifies the operation history to account for a detected cumulative operation. In some cases, the object-level undo system 102 performs an act 408 to exclude a previous operation from an operation history. For example, the object-level undo system 102 determines the previous operation that is a precursor or a foundation for a cumulative operation. The object-level undo system 102 further excludes the previous operation from the operation history or otherwise marks the previous operation as non-undoable. Indeed, because the cumulative operation cumulatively adds to, and relies on, a modification from the previous operation, the previous operation is a prerequisite for the cumulative operation, and the cumulative operation would not be possible without it. Thus, the object-level undo system 102 disables undoing the previous operation by excluding or otherwise labeling the previous operation in the operation history. As indicated by the strikethrough in FIG. 4, the object-level undo system 102 removes or excludes the previous operation from the operation history.

In certain cases, the object-level undo system 102 modifies the operation history by performing an act 410 to merge the cumulative operation with one or more previous operations. For example, the object-level undo system 102 identifies a previous operation relied on by a cumulative operation. In addition, the object-level undo system 102 merges or combines the previous operation with the cumulative operation within the operation history, effectively combining multiple operations into a single operation within the history. The object-level undo system 102 thus generates a merged edit operation that includes an object label, a timestamp (e.g., for one or both of the previous operation and the cumulative operation) and/or pixels locations for pixels modified by both the previous edit and the cumulative edit.

Based on modifying an operation history to account for cumulative edit operations, the object-level undo system 102 performs a selective object-level undo operation using the modified operation history. For instance, the object-level undo system 102 generates an interface element for selecting an object-specific edit operation, where the interface element includes indicators for individual edit operations applied to a selected object. Within the interface element, the object-level undo system 102 generates an indicator for a merged edit operation and/or excludes an indicator for a previous edit operation that underpins a cumulative edit operation. The object-level undo system 102 further undoes a selected merged operation and/or cumulative operation based on a selection of a corresponding indicator within the interface element.

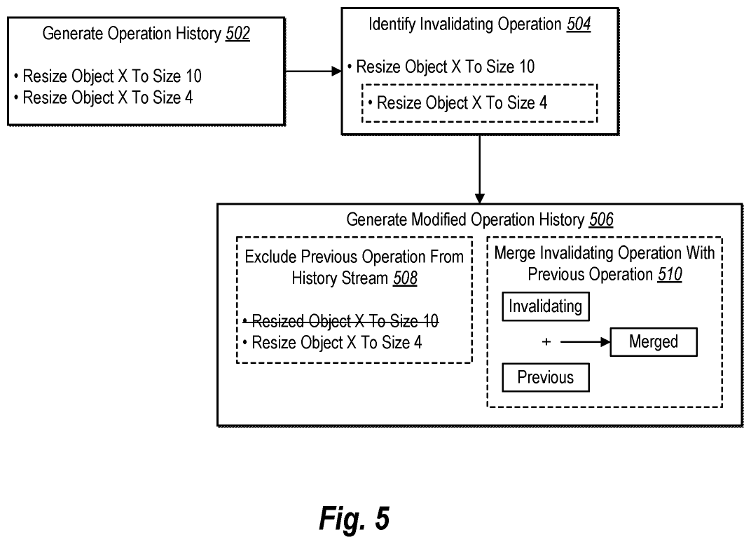

As indicated above, in certain embodiments, the object-level undo system 102 generates and updates an operation history to account for invalidating edit operations. In particular, the object-level undo system 102 detects an invalidating edit operation and modifies an operation history accordingly. FIG. 5 illustrates an example diagram for modifying an operation history based on detecting an invalidating edit operation in accordance with one or more embodiments.

As illustrated in FIG. 5, the object-level undo system 102 performs an act 502 to generate an operation history. As described above, to generate an operation history, the object-level undo system 102 detects edit operations performed within a digital design and generates operation logs for the edit operations. Indeed, the object-level undo system 102 adds a new operation log to the operation history that includes operation metadata indicating, for example, an object label, an operation type, and a timestamp. Over time, the object-level undo system 102 thus generates an operation history (or multiple object-specific operation histories) that includes a series of edit operations performed in a digital design.

As also illustrated in FIG. 5, the object-level undo system 102 performs an act 504 to identify an invalidating edit operation. In some embodiments, an invalidating operation includes or refers to an edit operation that invalidates, obviates, nullifies, overwrites, or renders moot one or more previous edit operations. For example, an invalidating operation overwrites the same set of parameters modified by a previous edit operation, replacing the previous modification with a new one. The object-level undo system 102 identifies or detects an invalidating edit operation by determining that an edit operation overwrites or nullifies a previous operation among the series of operations in the operation history.

As further illustrated in FIG. 5, the object-level undo system 102 performs an act 506 to generate a modified operation history. In particular, the object-level undo system 102 modifies the operation history to account for a detected invalidating operation. In some cases, the object-level undo system 102 performs an act 508 to exclude a previous operation from an operation history. For example, the object-level undo system 102 determines the previous operation that is invalidated by an invalidating operation. The object-level undo system 102 further excludes the invalidated previous operation from the operation history or otherwise marks the previous operation as non-undoable. Indeed, because the invalidating operation invalidates the previous operation, as a practical matter, undoing the previous operation would result in no visible change to the modified object because any edited object values would still reflect the changes from the subsequent invalidating operation. Thus, the object-level undo system 102 disables undoing the previous operation by excluding or otherwise labeling the previous operation in the operation history.

In certain cases, the object-level undo system 102 modifies the operation history by performing an act 510 to merge the invalidating operation with one or more (invalidated) previous operations. For example, the object-level undo system 102 merges or combines the previous operation with the invalidating operation within the operation history, effectively combining multiple operations into a single merged operation within the history. The object-level undo system 102 thus generates a merged edit operation that includes an object label, a timestamp (e.g., for one or both of the previous operation and the invalidating operation) and/or pixels locations for pixels modified by both the previous edit and the invalidating edit.

Based on modifying an operation history to account for invalidating edit operations, the object-level undo system 102 performs a selective object-level undo operation using the modified operation history. For instance, the object-level undo system 102 generates an interface element for selecting an object-specific edit operation, where the interface element includes indicators for individual edit operations applied to a selected object. Within the interface element, the object-level undo system 102 generates an indicator for a merged edit operation and/or excludes an indicator for a previous edit operation that invalidated by an invalidating edit operation. The object-level undo system 102 further undoes a selected merged operation and/or a selected invalidating operation based on a selection of a corresponding indicator within the interface element.

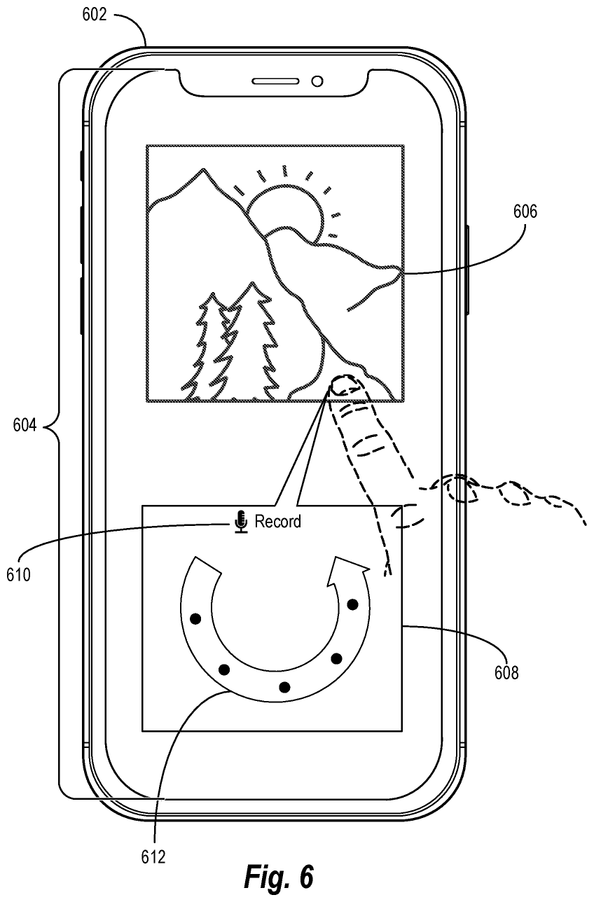

As mentioned above, in certain described embodiments, the object-level undo system 102 generates and provides user interface elements for performing selective object-level undo operations. In particular, the object-level undo system 102 provides elements for gesture and/or voice inputs to select object-specific operations to undo from an operation history. FIG. 6 illustrates an example digital design interface for performing selective object-level undo operations in accordance with one or more embodiments.

As illustrated in FIG. 6, the object-level undo system 102 generates and provides a digital design interface 604 for display on a client device 602. As shown, the client device 602 is a mobile device, and the object-level undo system 102 generates and provides interface elements for efficiently performing selective object-level undo operations, even within the limited screen space of the mobile device. Within the digital design interface 604, the object-level undo system 102 provides a visualization of a digital design 606. In addition, the object-level undo system 102 provides one or more editing tools for generating and modifying the digital design 606.

Among the interface elements and editing tools, the object-level undo system 102 generates and provides a selective object-level undo element 608 in response to a selection of an object within the digital design 606. For example, the object-level undo system 102 receives a tap, a click, or some other input selecting the lake object within the digital design 606. In response, the object-level undo system 102 generates and provides the selective object-level undo element 608. Within the selective object-level undo element 608, the object-level undo system 102 provides a voice input element 610 and/or an undo element 612.

Based on detecting or receiving a selection of the voice input element 610, the object-level undo system 102 engages or initiates a microphone of the client device 602 to capture voice input specifying a particular operation or operation type to undo for the selected lake object. In some embodiments, an operation type includes or refers to a category or identification of edit operations performable to modify a digital design. For example, operation types can include categories such as color changes, pixel location changes, brightness changes, opacity changes, edits related to filters, layer changes, size/scale changes, added lines, removed lines, additional or removal of effects (e.g., blur, pixelate, sharpen, etc.), and/or other modification types. In some cases, the object-level undo system 102 thus captures a spoken voice input to specify an operation type for an operation to undo for a selected object.

Based on detecting or receiving a selection of the undo element 612, the object-level undo system 102 determines or identifies a particular operation to undo from among a series of operations performed on the lake object. For example, the object-level undo system 102 generates and provides a circular (or semi-circular) arrow element that includes operation-specific indicators (the black dots) for edit operations performed on the selected lake object (as indicated by an operation history). The object-level undo system 102 further receives an input to drag the arrowhead in a reverse direction to effectively rewind through states of the selected lake object to select an operation to undo (while leaving other operations unchanged). In some cases, the object-level undo system 102 provides popup indicators to explain or depict a currently selected edit operation during the drag input via the undo element 612. In these or other cases, the object-level undo system 102 visually updates the selected lake object extemporaneously with the drag input to visualize a preview (within the digital design 606) of the changes if applied to undo a selected operation.

In some embodiments, the object-level undo system 102 generates and provides a voice input element within the digital design interface 604 without first requiring a selection of an object. Thus, based on a selection of the voice input element, the object-level undo system 102 engages a microphone function to capture voice input specifying a particular object to select and/or a particular operation type to undo for a selected object. In some embodiments, the object-level undo system 102 engages the microphone to capture a spoken “undo” command which triggers the object-level undo system 102 to provide an undo element (e.g., the undo element 612) for selecting an operation to undo from among a series of edit operations performed on a selected object. In certain embodiments, the object-level undo system 102 engages the microphone to capture a spoken “undo” command upon selection of an object (e.g., the lake) in the digital design 606—without expressly requiring additional interaction with a record element—to then trigger presentation of an undo element.

In some cases, the object-level undo system 102 receives a combined (e.g., hybrid) input that includes a voice component and a gesture component together. For instance, the object-level undo system 102 receives a combined input with a gesture component selecting the lake object and a voice component indicating an operation to undo from among a series of operation performed on the object. As another example, the object-level undo system 102 receives a combined input with a voice component indicating an object to select and a gesture component indicating an operation to undo among a series of object-specific edit operations.

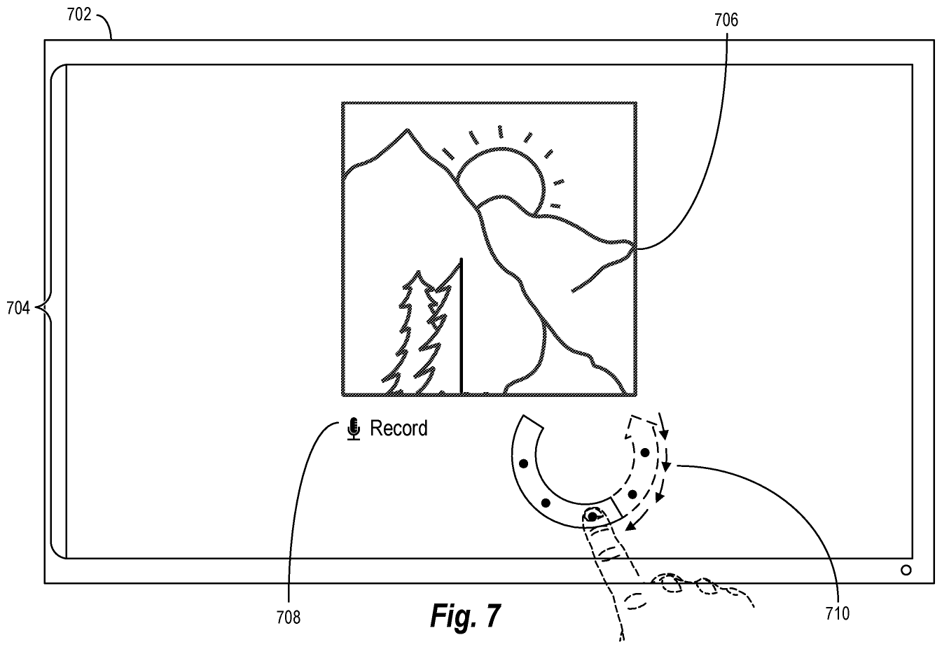

As mentioned above, in certain embodiments, the object-level undo system 102 generates and provides a modified digital design based on performing a selective object-level undo operation. In particular, the object-level undo system 102 modifies an object within a digital design by undoing a selected object-specific edit operation. FIG. 7 illustrates an example digital design interface for performing a selective object-level undo operation in accordance with one or more embodiments.

As illustrated in FIG. 7, the object-level undo system 102 generates and provides a digital design 706 for display within a digital design interface 704 on a client device 702. For example, the object-level undo system 102 generates a design of mountain scenery that includes various objects, such as a sun object, multiple mountain objects, multiple tree objects, and a lake object. As shown, the object-level undo system 102 further generates and provides interface elements for performing a selective object-level undo operation.

More specifically, the object-level undo system 102 provides a voice input element 708 and/or an undo element 710. The undo element 710 includes indications for undoable edit operations performed on a selected object, including merged operations (or excluding previous operations) corresponding to cumulative or invalidating operations as describe above. As indicated above, the object-level undo system 102 can receive a combined input that includes a voice component received via the voice input element 708 and a gesture component received via the undo element 710. For instance, the object-level undo system 102 receives a voice input indicating or selecting an object within the digital design 706 (e.g., a verbal indication of “foreground tree”). In addition, the object-level undo system 102 receives a gesture input (via the undo element 710) to select an operation to undo for the selected foreground tree object.

As shown, the object-level undo system 102 receives a drag input (circularly in a reverse direction of the arrow) to skip the most recent two edit operation and to select the third operation in the timeline to undo. As also shown, the object-level undo system 102 performs the selective object-level undo operation to undo the addition of a portion of the selected foreground tree (e.g., by removing the added lines) while preserving (or automatically reapplying) the subsequent operations in the timeline. Indeed, the object-level undo system 102 generates and provides a modified version of the digital design 706 that depicts the object modified according to the selective object-level undo operation.

In some embodiments, the object-level undo system 102 receives a combined input that includes multiple gesture components along with a voice component, including: a first gesture input selecting an object in the digital design 706, a voice input indicating a request to perform a selective object-level undo operation (e.g., a verbal “undo” command), and a second gesture input via the undo element 710 to select the operation to undo. For example, the first gesture input triggers the object-level undo system 102 to provide a voice input element indicating that the client device 702 is recording audio data. Thus, the object-level undo system 102 receives the voice input which triggers the object-level undo system 102 to provide the undo element 710. Finally, the object-level undo system 102 receives a selection of an operation to undo via the undo element 710.

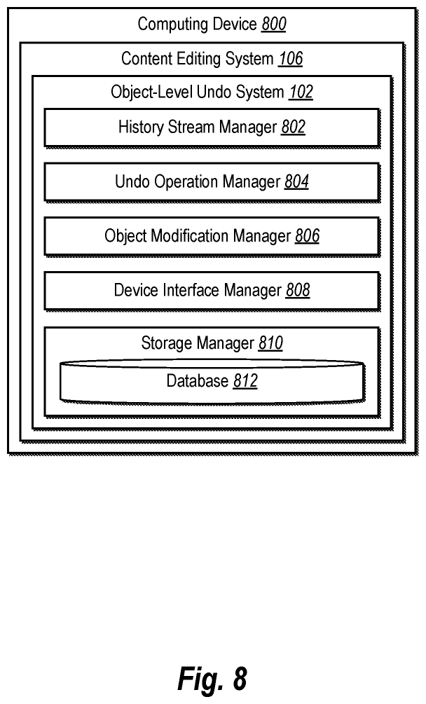

Looking now to FIG. 8, additional detail will be provided regarding components and capabilities of the object-level undo system 102. Specifically, FIG. 8 illustrates an example schematic diagram of the object-level undo system 102 on an example computing device 800 (e.g., one or more of the client device 108 and/or the server(s) 104). In some embodiments, the computing device 800 refers to a distributed computing system where different managers are located on different devices, as described above. As shown in FIG. 8, the object-level undo system 102 includes a history stream manager 802, an undo operation manager 804, an object modification manager 806, a device interface manager 808, and a storage manager 810.

As just mentioned, the object-level undo system 102 includes a history stream manager 802. In particular, the history stream manager 802 manages, maintains, generates, updates, and/or modifies a history stream or an operation history. For example, the history stream manager 802 adds operations logs and corresponding operation metadata to a global operation history for a digital design. As another example, the history stream manager 802 logs operations and operation metadata in multiple object-specific operation histories. The history stream manager 802 further updates an operation history to remove an operation undone by a selective object-level undo operation. In addition, the history stream manager 802 updates an operation history to account for cumulative operations and/or invalidating operations, as described herein.

As shown, the object-level undo system 102 includes an undo operation manager 804. In particular, the undo operation manager 804 manages, maintains, applies, executes, performs, or carries out a selective object-level undo operation. For example, the undo operation manager 804 undoes a selected edit operation performed on a particular object while preserving (or automatically reapplying) other edits performed within the digital design (e.g., to the same object or other objects). In some cases, the undo operation manager 804 reverses a state of a selected object to undo operations in reverse chronological order until the selected operation is undone, and then the undo operation manager 804 reapplies the subsequent operations after the undone operation.

Additionally, the object-level undo system 102 includes an object modification manager 806. In particular, the object modification manager 806 manages, maintains, updates, modifies, generates, or augments objects depicted within a digital design. For example, the object modification manager 806 modifies visible and/or non-visible parameters of an object as part of performing a selective object-level undo operation on the object. Indeed, the object modification manager 806 modifies a selected object to change the appearance of an object by reversing or undoing an operation, while preserving other operations.

As further shown, the object-level undo system 102 includes a device interface manager 808. In particular, the device interface manager 808 manages user interfaces of a digital design application, including generating and providing interface elements for performing selective object-level undo operations. For instance, the device interface manager 808 generates and provides voice input elements and/or gesture input elements for receiving requests for selective object-level undo operations. The device interface manager 808 further receives such interactions and communications with other components of the object-level undo system 102 to perform a selective object-level undo operation for modifying one or more depicted objects.

The object-level undo system 102 further includes a storage manager 810. The storage manager 810 operates in conjunction with, or includes, one or more memory devices such as the database 812 (e.g., the database 114) that store various data such as digital designs, objects, object data, and/or an operation history including operation metadata. As shown, the storage manager 810 also stores and maintains one or more object detection models for detecting and labeling objects in a digital design. The storage manager 810 communicates with the other components of the object-level undo system 102 to facilitate the operations and functions described herein.

In one or more embodiments, each of the components of the object-level undo system 102 are in communication with one another using any suitable communication technologies. Additionally, the components of the object-level undo system 102 is in communication with one or more other devices including one or more client devices described above. It will be recognized that although the components of the object-level undo system 102 are shown to be separate in FIG. 8, any of the subcomponents may be combined into fewer components, such as into a single component, or divided into more components as may serve a particular implementation. Furthermore, although the components of FIG. 8 are described in connection with the object-level undo system 102, at least some of the components for performing operations in conjunction with the object-level undo system 102 described herein may be implemented on other devices within the environment.

The components of the object-level undo system 102, in one or more implementations, includes software, hardware, or both. For example, the components of the object-level undo system 102 include one or more instructions stored on a computer-readable storage medium and executable by processors of one or more computing devices (e.g., the computing device 800). When executed by the one or more processors, the computer-executable instructions of the object-level undo system 102 cause the computing device 800 to perform the methods described herein. Alternatively, the components of the object-level undo system 102 comprises hardware, such as a special purpose processing device to perform a certain function or group of functions. Additionally, or alternatively, the components of the object-level undo system 102 includes a combination of computer-executable instructions and hardware.

Furthermore, the components of the object-level undo system 102 performing the functions described herein may, for example, be implemented as part of a stand-alone application, as a module of an application, as a plug-in for applications including content management applications, as a library function or functions that may be called by other applications, and/or as a cloud-computing model. Thus, the components of the object-level undo system 102 may be implemented as part of a stand-alone application on a personal computing device or a mobile device. Alternatively, or additionally, the components of the object-level undo system 102 may be implemented in any application that allows creation and delivery of marketing content to users, including, but not limited to, applications in ADOBE® EXPERIENCE MANAGER and CREATIVE CLOUD®, such as ADOBE® FIREFLY, ADOBE® EXPRESS, PHOTOSHOP®, ILLUSTRATOR®, and INDESIGN®. “ADOBE,” “ADOBE EXPERIENCE MANAGER,” “CREATIVE CLOUD,” “ADOBE FIREFLY,” “ADOBE EXPRESS,” “PHOTOSHOP,” “ILLUSTRATOR,” and “INDESIGN” are either registered trademarks or trademarks of Adobe Inc. in the United States and/or other countries.

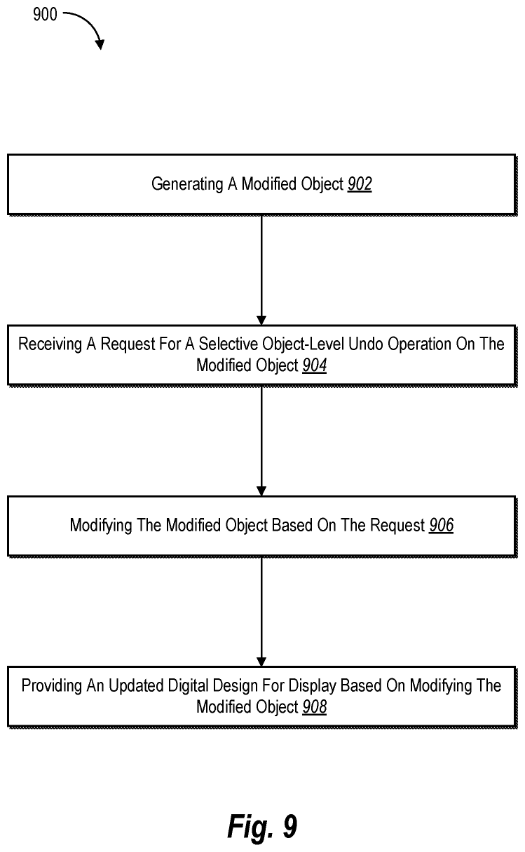

FIGS. 1-8 the corresponding text, and the examples provide a number of different systems, methods, and non-transitory computer readable media for modifying a digital design by performing a selective object-level undo operation. In addition to the foregoing, embodiments are describable in terms of flowcharts comprising acts for accomplishing a particular result. For example, FIG. 9 illustrates a flowchart of an example sequence or series of acts in accordance with one or more embodiments.

While FIG. 9 illustrates acts according to one or more embodiments, alternative embodiments may omit, add to, reorder, and/or modify any of the acts shown in FIG. 9. The acts of FIG. 9 are sometimes performed as part of a method. Alternatively, a non-transitory computer readable medium comprises instructions, that when executed by one or more processors, cause a computing device to perform the acts of FIG. 9. In still further embodiments, a system performs the acts of FIG. 9. Additionally, the acts described herein may be repeated or performed in parallel with one another or in parallel with different instances of the same or other similar acts.

FIG. 9 illustrates an example series of acts 900 for modifying a digital design by performing a selective object-level undo operation. The series of acts 900 includes an act 902 of generating a modified object. In particular, the act 902 involves generating, as part of a digital design, a modified object by performing a series of operations on an object depicted within the digital design. In addition, the series of acts 900 includes an act 904 of receiving a request for a selective object-level undo operation on the modified object. In particular, the act 904 involves receiving, from a client device, a request for a selective object-level undo operation on the modified object, wherein the request specifies an operation to undo from among the series of operations performed on the object. As shown, the series of acts 900 includes an act 906 of modifying the modified object based on the request. In particular, the act 906 involves modifying, in response to the request, the modified object by performing the selective object-level undo operation on the modified object to undo the operation from among the series of operations. Further, the series of acts 900 includes an act 908 of providing an updated digital design for display based on modifying the modified object. In particular, the act 908 involves providing, for display on the client device, an updated digital design depicting an updated version of the modified object reflecting modifications from the series of operations excluding the operation undone by the selective object-level undo operation.

In some embodiments, the series of acts 900 includes an act of receiving the request for the selective object-level undo operation by receiving an indication to undo an intermediate operation that occurred before a final operation of the series of operations on the object. In these or other embodiments, the series of acts 900 includes an act of modifying the modified object by performing the selective object-level undo operation to undo a specified type of edit made to the object as part of the series of operations. Additionally, the series of acts 900 includes an act of providing, for display on the client device, an interface element for selecting the operation to undo from among the series of operations performed on the object and an act of excluding, from the interface element, global operations performed on the digital design as a whole and operations performed specific to other objects within the digital design.

In certain embodiments, the series of acts 900 includes an act of identifying, as part of the series of operations performed to generate the modified object, a cumulative edit that relies on modifications applied from a previous edit. Additionally, the series of acts 900 includes an act of providing, for display on the client device, an interface element depicting undoable operations for the modified object and excluding the previous edit. Further, the series of acts 900 includes acts of generating a global history of operations performed within the digital design, the global history comprising indications of operation types and objects where the operations were applied and modifying the modified object by undoing the operation indicated by the selective object-level undo operation within the global history. The series of acts 900 also includes acts of providing, for display within a digital design interface on the client device, a selective undo element indicating the series of operations performed to generate the modified object and receiving the request for the selective object-level undo operation by receiving a selection within the selective undo element of the operation to undo from among the series of operations.

In some embodiments, the series of acts 900 includes an act of generating, as part of a digital design, a first modified object and a second modified object modified after the first modified object within the digital design. In addition, the series of acts 900 includes an act of receiving, from a client device, a request for a selective object-level undo operation on the first modified object, wherein the request specifies an operation to undo from among a series of operations performed to generate the first modified object. Additionally, the series of acts 900 includes an act of modifying, in response to the request, the first modified object by performing the selective object-level undo operation on the first modified object to undo the operation. Further, the series of acts 900 includes an act of providing, for display on the client device, an updated digital design depicting the second modified object and an updated version of the first modified object reflecting modifications from the series of operations excluding the operation undone by the selective object-level undo operation.

In certain cases, the series of acts 900 includes an act of receiving the request for the selective object-level undo operation by receiving a combined input comprising a gesture component indicating the first modified object and voice component indicating the operation to undo from among the series of operations performed to generate the first modified object. In addition, the series of acts 900 includes an act of modifying the first modified object by performing the selective object-level undo operation to undo the operation within a first layer of the digital design and to retain remaining operations of the series of operations performed to generate the first modified object.

In one or more embodiments, the series of acts 900 includes acts of identifying, as part of the series of operations performed to generate the first modified object, an invalidating operation that invalidates a previous operation and providing, for display on the client device, an interface element depicting undoable operations for the first modified object and excluding the previous operation. In addition, the series of acts 900 includes acts of generating, for the digital design, an operation history of operations performed within the digital design, identifying, within the operation history, a cumulative operation that relies on modifications applied from a previous operation, and generating a modified operation history comprising a merged operation by merging the cumulative operation with the previous operation to render the merged operation undoable.

In some cases, the series of acts 900 includes an act of modifying the first modified object by performing the selective object-level undo operation to undo the operation within a first layer of the digital design without impacting the second modified object within the digital design within a second layer of the digital design. In addition, the series of acts 900 includes an act of generating a global history comprising object identifiers and operation identifiers for operations performed across a plurality of objects within the digital design and an act of, in response to the request for the selective object-level undo operation, determining an object identifier and an operation identifier for the operation to undo from among the series of operations performed to generate the first modified object.

In some embodiments, the series of acts 900 includes an act of providing, for display on the client device, a selective undo element comprising a circular timeline indicating a chronology of operations performed to generate the modified object. In these or other embodiments, the series of acts 900 includes an act of receiving the request for the selective object-level undo operation by receiving a circular drag input for navigating through the chronology of operations to locate the operation to undo.

Additionally, the series of acts 900 includes acts of generating, for the digital design, an operation history of operations performed within the digital design, identifying, within the operation history, an invalidating operation that invalidates a previous operation, and generating a modified operation history comprising a merged operation by merging the invalidating operation with the previous operation to render the merged operation undoable. Further, the series of acts 900 includes an act of providing the updated digital design for display by providing the updated version of the modified object and maintaining visual attributes of other objects within the digital design. In addition, the series of acts 900 includes an act of receiving the request for the selective object-level undo operation by receiving an indication to undo an intermediate operation that occurred before a final operation of the series of operations on the object. Additionally, the series of acts 900 includes an act of modifying the modified object by, in response to the request for the selective object-level undo operation, undoing the intermediate operation and maintaining the final operation.

Embodiments of the present disclosure may comprise or use a special purpose or general-purpose computer including computer hardware, such as, for example, one or more processors and system memory, as discussed in greater detail below. Embodiments within the scope of the present disclosure also include physical and other computer-readable media for carrying or storing computer-executable instructions and/or data structures. In particular, one or more of the processes described herein may be implemented at least in part as instructions embodied in a non-transitory computer-readable medium and executable by one or more computing devices (e.g., any of the media content access devices described herein). In general, a processor (e.g., a microprocessor) receives instructions, from a non-transitory computer-readable medium, (e.g., memory), and executes those instructions, thereby performing one or more processes, including one or more of the processes described herein.

Computer-readable media can be any available media that can be accessed by a general purpose or special purpose computer system. Computer-readable media that store computer-executable instructions are non-transitory computer-readable storage media (devices). Computer-readable media that carry computer-executable instructions are transmission media. Thus, by way of example, and not limitation, embodiments of the disclosure can comprise at least two distinctly different kinds of computer-readable media: non-transitory computer-readable storage media (devices) and transmission media.

Non-transitory computer-readable storage media (devices) includes RAM, ROM, EEPROM, CD-ROM, solid state drives (“SSDs”) (e.g., based on RAM), Flash memory, phase-change memory (“PCM”), other types of memory, other optical disk storage, magnetic disk storage or other magnetic storage devices, or any other medium which can be used to store desired program code means in the form of computer-executable instructions or data structures and which can be accessed by a general purpose or special purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmissions media can include a network and/or data links which can be used to carry desired program code means in the form of computer-executable instructions or data structures and which can be accessed by a general purpose or special purpose computer. Combinations of the above should also be included within the scope of computer-readable media.

Further, upon reaching various computer system components, program code means in the form of computer-executable instructions or data structures can be transferred automatically from transmission media to non-transitory computer-readable storage media (devices) (or vice versa). For example, computer-executable instructions or data structures received over a network or data link can be buffered in RAM within a network interface module (e.g., a “NIC”), and then eventually transferred to computer system RAM and/or to less volatile computer storage media (devices) at a computer system. Thus, it should be understood that non-transitory computer-readable storage media (devices) can be included in computer system components that also (or even primarily) use transmission media.

Computer-executable instructions comprise, for example, instructions and data which, when executed by a processor, cause a general-purpose computer, special purpose computer, or special purpose processing device to perform a certain function or group of functions. In some embodiments, computer-executable instructions are executed by a general-purpose computer to turn the general-purpose computer into a special purpose computer implementing elements of the disclosure. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the disclosure may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, tablets, pagers, routers, switches, and the like. The disclosure may also be practiced in distributed system environments where local and remote computer systems, which are linked (either by hardwired data links, wireless data links, or by a combination of hardwired and wireless data links) through a network, both perform tasks. In a distributed system environment, program modules may be located in both local and remote memory storage devices.

Embodiments of the present disclosure can also be implemented in cloud computing environments. As used herein, the term “cloud computing” refers to a model for enabling on-demand network access to a shared pool of configurable computing resources. For example, cloud computing can be employed in the marketplace to offer ubiquitous and convenient on-demand access to the shared pool of configurable computing resources. The shared pool of configurable computing resources can be rapidly provisioned via virtualization and released with low management effort or service provider interaction, and then scaled accordingly.

A cloud-computing model can be composed of various characteristics such as, for example, on-demand self-service, broad network access, resource pooling, rapid elasticity, measured service, and so forth. A cloud-computing model can also expose various service models, such as, for example, Software as a Service (“SaaS”), Platform as a Service (“PaaS”), and Infrastructure as a Service (“IaaS”). A cloud-computing model can also be deployed using different deployment models such as private cloud, community cloud, public cloud, hybrid cloud, and so forth. In addition, as used herein, the term “cloud-computing environment” refers to an environment in which cloud computing is employed.

FIG. 10 illustrates a block diagram of an example computing device 1000 that may be configured to perform one or more of the processes described above. One will appreciate that one or more computing devices, such as the computing device 1000 may represent the computing devices described above (e.g., computing device 800, server(s) 104, and/or client device 108). In one or more embodiments, the computing device 1000 may be a mobile device (e.g., a mobile telephone, a smartphone, a PDA, a tablet, a laptop, a camera, a tracker, a watch, a wearable device, etc.). In some embodiments, the computing device 1000 may be a non-mobile device (e.g., a desktop computer or another type of client device). Further, the computing device 1000 may be a server device that includes cloud-based processing and storage capabilities.

As shown in FIG. 10, the computing device 1000 can include one or more processor(s) 1002, memory 1004, a storage device 1006, input/output interfaces 1008 (or “I/O interfaces 1008”), and a communication interface 1010, which may be communicatively coupled by way of a communication infrastructure (e.g., bus 1012). While the computing device 1000 is shown in FIG. 10, the components illustrated in FIG. 10 are not intended to be limiting. Additional or alternative components may be used in other embodiments. Furthermore, in certain embodiments, the computing device 1000 includes fewer components than those shown in FIG. 10. Components of the computing device 1000 shown in FIG. 10 will now be described in additional detail.

In particular embodiments, the processor(s) 1002 includes hardware for executing instructions, such as those making up a computer program. As an example, and not by way of limitation, to execute instructions, the processor(s) 1002 may retrieve (or fetch) the instructions from an internal register, an internal cache, memory 1004, or a storage device 1006 and decode and execute them.

The computing device 1000 includes memory 1004, which is coupled to the processor(s) 1002. The memory 1004 may be used for storing data, metadata, and programs for execution by the processor(s). The memory 1004 may include one or more of volatile and non-volatile memories, such as Random-Access Memory (“RAM”), Read-Only Memory (“ROM”), a solid-state disk (“SSD”), Flash, Phase Change Memory (“PCM”), or other types of data storage. The memory 1004 may be internal or distributed memory.

The computing device 1000 includes a storage device 1006 includes storage for storing data or instructions. As an example, and not by way of limitation, the storage device 1006 can include a non-transitory storage medium described above. The storage device 1006 may include a hard disk drive (HDD), flash memory, a Universal Serial Bus (USB) drive or a combination these or other storage devices.

As shown, the computing device 1000 includes one or more I/O interfaces 1008, which are provided to allow a user to provide input to (such as user strokes), receive output from, and otherwise transfer data to and from the computing device 1000. These I/O interfaces 1008 may include a mouse, keypad or a keyboard, a touch screen, camera, optical scanner, network interface, modem, other known I/O devices or a combination of such I/O interfaces 1008. The touch screen may be activated with a stylus or a finger.

The I/O interfaces 1008 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O interfaces 1008 are configured to provide graphical data to a display for presentation to a user. The graphical data may be representative of one or more graphical user interfaces and/or any other graphical content as may serve a particular implementation.

The computing device 1000 can further include a communication interface 1010. The communication interface 1010 can include hardware, software, or both. The communication interface 1010 provides one or more interfaces for communication (such as, for example, packet-based communication) between the computing device and one or more other computing devices or one or more networks. As an example, and not by way of limitation, communication interface 1010 may include a network interface controller (NIC) or network adapter for communicating with an Ethernet or other wire-based network or a wireless NIC (WNIC) or wireless adapter for communicating with a wireless network, such as a WI-FI. The computing device 1000 can further include a bus 1012. The bus 1012 can include hardware, software, or both that connects components of computing device 1000 to each other.

In the foregoing specification, the invention has been described with reference to specific example embodiments thereof. Various embodiments and aspects of the invention(s) are described with reference to details discussed herein, and the accompanying drawings illustrate the various embodiments. The description above and drawings are illustrative of the invention and are not to be construed as limiting the invention. Numerous specific details are described to provide a thorough understanding of various embodiments of the present invention.

The present invention may be embodied in other specific forms without departing from its spirit or essential characteristics. The described embodiments are to be considered in all respects only as illustrative and not restrictive. For example, the methods described herein may be performed with less or more steps/acts or the steps/acts may be performed in differing orders. Additionally, the steps/acts described herein may be repeated or performed in parallel to one another or in parallel to different instances of the same or similar steps/acts. The scope of the invention is, therefore, indicated by the appended claims rather than by the foregoing description. All changes that come within the meaning and range of equivalency of the claims are to be embraced within their scope.

What is claimed is:

1. A computer-implemented method comprising:
generating, as part of a digital design, a modified object by performing a series of operations on an object depicted within the digital design;
receiving, from a client device, a request for a selective object-level undo operation on the modified object, wherein the request specifies an operation to undo from among the series of operations performed on the object;
modifying, in response to the request, the modified object by performing the selective object-level undo operation on the modified object to undo the operation from among the series of operations; and
providing, for display on the client device, an updated digital design depicting an updated version of the modified object reflecting modifications from the series of operations excluding the operation undone by the selective object-level undo operation.

2. The computer-implemented method of claim 1, wherein receiving the request for the selective object-level undo operation comprises receiving an indication to undo an intermediate operation that occurred before a final operation of the series of operations on the object.

3. The computer-implemented method of claim 1, wherein modifying the modified object comprises performing the selective object-level undo operation to undo a specified type of edit made to the object as part of the series of operations.

4. The computer-implemented method of claim 1, further comprising:
providing, for display on the client device, an interface element for selecting the operation to undo from among the series of operations performed on the object; and
excluding, from the interface element, global operations performed on the digital design as a whole and operations performed specific to other objects within the digital design.

5. The computer-implemented method of claim 1, further comprising:
identifying, as part of the series of operations performed to generate the modified object, a cumulative edit that relies on modifications applied from a previous edit; and
providing, for display on the client device, an interface element depicting undoable operations for the modified object and excluding the previous edit.

6. The computer-implemented method of claim 1, further comprising:
generating a global history of operations performed within the digital design, the global history comprising indications of operation types and objects where the operations were applied; and
modifying the modified object by undoing the operation indicated by the selective object-level undo operation within the global history.

7. The computer-implemented method of claim 1, further comprising:
providing, for display within a digital design interface on the client device, a selective undo element indicating the series of operations performed to generate the modified object; and
receiving the request for the selective object-level undo operation by receiving a selection within the selective undo element of the operation to undo from among the series of operations.

8. A system comprising:
one or more memory devices; and
one or more processors coupled to the one or more memory devices, the one or more processors configured to cause the system to perform operations comprising:
generating, as part of a digital design, a first modified object and a second modified object modified after the first modified object within the digital design;
receiving, from a client device, a request for a selective object-level undo operation on the first modified object, wherein the request specifies an operation to undo from among a series of operations performed to generate the first modified object;
modifying, in response to the request, the first modified object by performing the selective object-level undo operation on the first modified object to undo the operation; and
providing, for display on the client device, an updated digital design depicting the second modified object and an updated version of the first modified object reflecting modifications from the series of operations excluding the operation undone by the selective object-level undo operation.

9. The system of claim 8, wherein receiving the request for the selective object-level undo operation comprises receiving a combined input comprising a gesture component indicating the first modified object and voice component indicating the operation to undo from among the series of operations performed to generate the first modified object.

10. The system of claim 8, wherein modifying the first modified object comprises performing the selective object-level undo operation to undo the operation and to retain remaining operations of the series of operations performed to generate the first modified object.

11. The system of claim 8, wherein the operations further comprise:
identifying, as part of the series of operations performed to generate the first modified object, an invalidating operation that invalidates a previous operation; and
providing, for display on the client device, an interface element depicting undoable operations for the first modified object and excluding the previous operation.

12. The system of claim 8, wherein the operation further comprise:
generating, for the digital design, an operation history of operations performed within the digital design;
identifying, within the operation history, a cumulative operation that relies on modifications applied from a previous operation; and
generating a modified operation history comprising a merged operation by merging the cumulative operation with the previous operation to render the merged operation undoable.

13. The system of claim 8, wherein modifying the first modified object comprises performing the selective object-level undo operation to undo the operation within a first layer of the digital design without impacting the second modified object within a second layer of the digital design.

14. The system of claim 8, wherein the operations further comprise:
generating a global history comprising object identifiers and operation identifiers for operations performed across a plurality of objects within the digital design; and
in response to the request for the selective object-level undo operation, determining an object identifier and an operation identifier for the operation to undo from among the series of operations performed to generate the first modified object.

15. A non-transitory computer readable medium storing executable instructions which, when executed by a processing device, cause the processing device to perform operations comprising:
generating, as part of a digital design, a modified object by performing a series of operations on an object depicted within the digital design;
receiving, from a client device, a request for a selective object-level undo operation on the modified object, wherein the request specifies an operation to undo from among the series of operations performed on the object;
modifying, in response to the request, the modified object by performing the selective object-level undo operation on the modified object to undo the operation from among the series of operations; and
providing, for display on the client device, an updated digital design depicting an updated version of the modified object reflecting modifications from the series of operations excluding the operation undone by the selective object-level undo operation.

16. The non-transitory computer readable medium of claim 15, wherein the operations further comprise:
providing, for display on the client device, a selective undo element comprising a circular timeline indicating a chronology of operations performed to generate the modified object; and
receiving the request for the selective object-level undo operation by receiving a circular drag input for navigating through the chronology of operations to locate the operation to undo.

17. The non-transitory computer readable medium of claim 15, wherein the operations further comprise:
generating, for the digital design, an operation history of operations performed within the digital design;
identifying, within the operation history, an invalidating operation that invalidates a previous operation; and
generating a modified operation history comprising a merged operation by merging the invalidating operation with the previous operation to render the merged operation undoable.

18. The non-transitory computer readable medium of claim 15, wherein providing the updated digital design for display comprises providing the updated version of the modified object and maintaining visual attributes of other objects within the digital design.

19. The non-transitory computer readable medium of claim 15, wherein receiving the request for the selective object-level undo operation comprises receiving an indication to undo an intermediate operation that occurred before a final operation of the series of operations on the object.

20. The non-transitory computer readable medium of claim 19, wherein modifying the modified object comprises, in response to the request for the selective object-level undo operation, undoing the intermediate operation and maintaining the final operation.
